(19) United States
(12) Patent Application Publication
(10) Pub. No.: US 2014/0131804 A1
(43) Pub. Date: May 15, 2014

(54) SEMICONDUCTOR STRUCTURE

(71) Applicant: UNITED MICROELECTRONIS CORP., Hsin-Chu City (TW)

(72) Inventors: Yi-Wei Chen, Taichung City (TW); Tsung-Hung Chang, Yunlin County (TW); I-Ming Tseng, Kaohsiung City (TW)

(73) Assignee: UNITED MICROELECTRONICS CORP., Hsin-Chu City (TW)

(21) Appl. No.: 13/674,103

(22) Filed: Nov. 12, 2012

(51) Int. Cl. H01L 29/78; H01L 21/768

(52) U.S. Cl. CPC H01L 29/78; H01L 21/768
USPC 257/368; 438/299

(57) ABSTRACT

The present invention provides a semiconductor structure, comprising at least two gate electrodes disposed on a substrate, wherein each gate electrode is mushroom-shaped and respectively has a salicide region on a top of the gate electrode, wherein the width of the salicide region is larger than the width of the gate electrode. A recess is disposed between each gate electrode, wherein the recess has a recess extension disposed under the salicide region. A spacer fills the extension of the recess, wherein the profile of each gate electrode is a tapered surface, and a contact etching stop layer (CESL) covers the gate electrodes.

### BACKGROUND OF THE INVENTION

1. Field of the Invention

The present invention relates to a semiconductor structure, and more particularly, to a manufacturing method for preventing an inter-dielectric layer (ILD) from having cavities or voids.

2. Description of the Prior Art

Metal-oxide-semiconductor (MOS) transistors are important components in semiconductor integrated circuits. The electrical performances of a gate and a source/drain in a MOS transistor greatly influence the efficiency of the MOS transistor. A salicide region is often formed on the gate or the source/drain, enabling good ohmic contacts for metal formed later on the gate or the source/drain, in order to reduce the sheet resistance of the gate and the source/drain, and enhance the operating velocity of the MOS transistor. After the salicide region is formed on the gate or the source/drain, the spacer beside the gate used to form the source/drain is removed, enabling a later-formed stress layer to be closer to a gate channel under the gate. This allows more stress to be induced in the gate channel which improves the carrier mobility in the gate channel. Then, a contact etch stop layer is formed to entirely cover the gate and the substrate, wherein the contact etch stop layer may force stress to the gate channel, and can be an etch stop layer when forming contact holes. After the spacer is removed and the contact etch stop layer is formed by the above method, an inter-dielectric layer is formed and contact holes are formed in the inter-dielectric layer by using the contact etch stop layer as an etch stop layer. Metal is then filled into the contact holes to form contact plugs.

As the contact holes are formed by said processing steps, cavities or voids will be generated between each of the gates after the inter-dielectric layer is covered, due to the too small spacing between each of the gates. This means the metal used to form the contact plugs will also fill the cavities or voids while filling the contact holes, leading to the contact plugs becoming electrically connected to each other and thereby creating short circuits.

### SUMMARY OF THE INVENTION

According to the claimed invention, a semiconductor structure is provided. The semiconductor structure comprises at least two gate electrodes disposed on a substrate, each of which is mushroom-shaped and respectively has a salicide region on a top of the gate electrodes, wherein the width of the salicide region is larger than the width of the gate electrode. A recess is disposed between each gate electrodes, wherein the recess having a recess extension is disposed under the salicide region. A spacer fills the extension of the recess, wherein the profile of each gate electrode is a tapered surface, and a contact etching stop layer (CESL) covers the gate electrodes.

According to the claimed invention, a method for forming a semiconductor structure is provided. First, at least two gate electrodes disposed on a substrate are provided. Next, a spacer disposed on two sides of each gate electrode is formed. Afterwards, an ion implantation process is performed on each gate electrodes to make each gate electrode become mushroom-shaped. A dry-etching process is performed to remove parts of the spacer and make the profile of the gate electrodes become a tapered surface. Thereafter, a salicide process is performed on each gate electrodes to form a salicide region disposed on each gate electrodes, wherein the width of the salicide region is larger than the width of the gate electrode. Finally, a contact etching stop layer (CESL) is formed on each gate electrodes.

The semiconductor structure according to the present invention provides a spacer to fill the recess extension disposed in parts of the gate electrode between any two of the adjacent gate electrodes. In addition, the unwanted spacer is entirely removed during the dry-etching process, so as to modify the profile of the gate electrode before performing the salicide process. Hence, the step coverage of the CESL formed in the following process can totally cover the substrate and fill the recesses without forming the cavities or voids. Therefore, the semiconductor structure can effectively prevent adjacent contact plugs from overhang, which would lead to the contact plugs to be electrically connected to each other and thereby creating short circuits.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1˜7 are schematic, cross-sectional view diagrams showing a method for fabricating a semiconductor structure according to a preferred embodiment of the present invention.

### DETAILED DESCRIPTION

To provide a better understanding of the present invention to those skilled in the art, preferred embodiments are detailed in the following. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

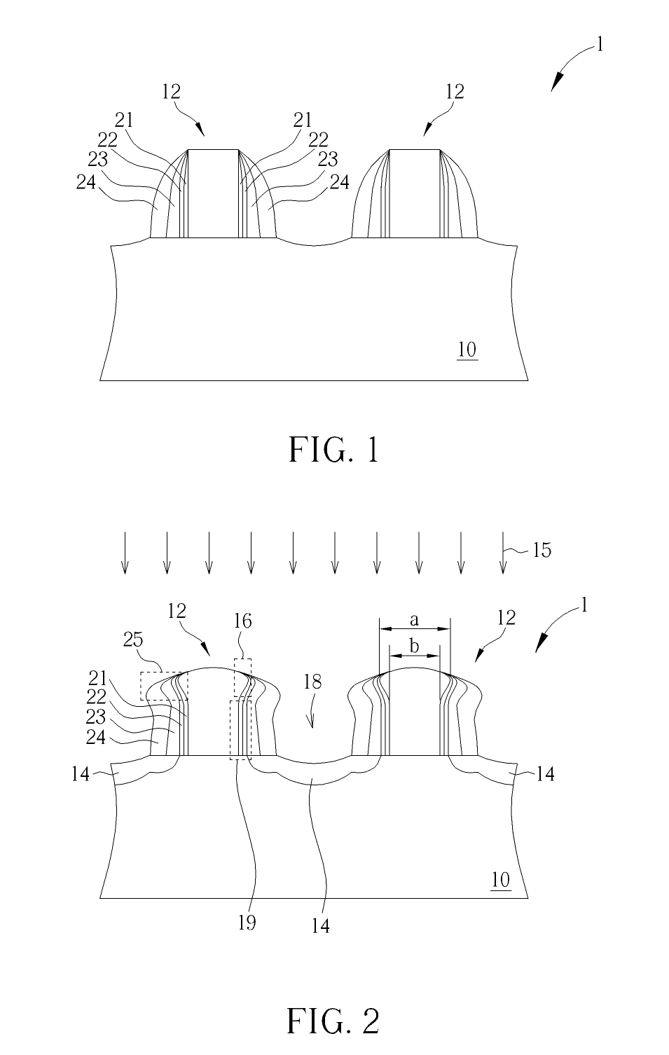

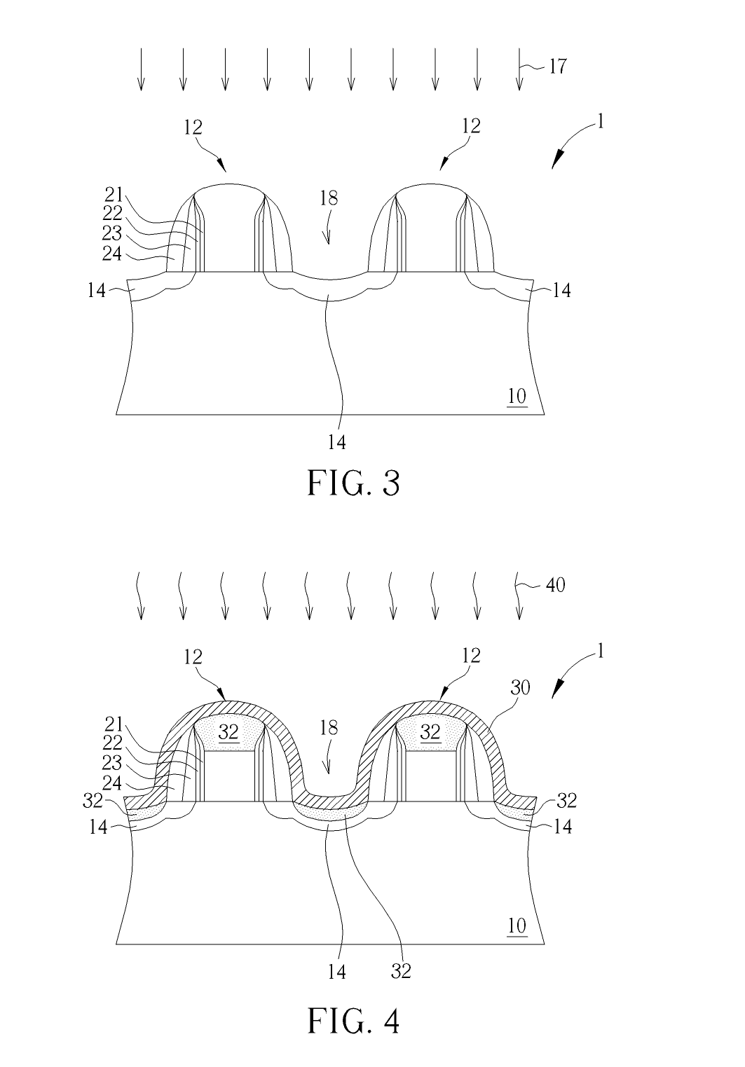

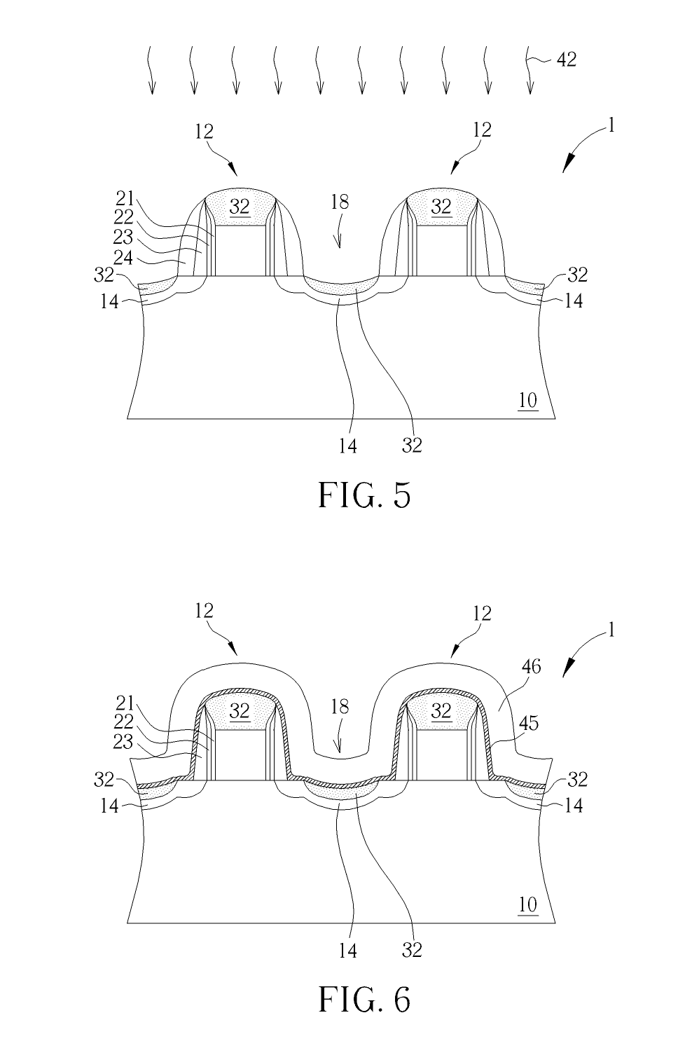

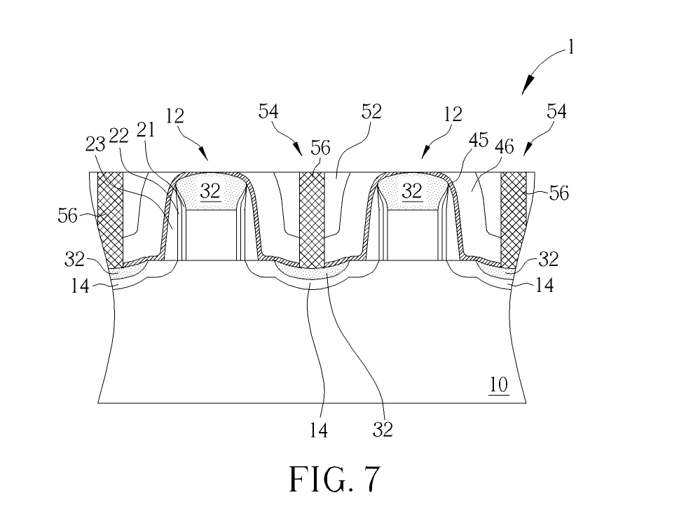

Please refer to FIGS. 1˜7, which are schematic, cross-sectional view diagrams showing a method for fabricating a semiconductor structure according to the first preferred embodiment of the present invention. As shown in FIG. 1, a substrate 10 is provided, wherein the substrate 10 may be a semiconductor substrate, such as a silicon substrate, a silicon containing substrate, a III-V group-on-silicon (such as GaN-on-silicon) substrate, a graphene-on-silicon substrate or a silicon-on-insulator (SOI) substrate. At least two gate electrodes 12 are formed on the substrate 10, wherein the material of each gate electrode 12 comprises polysilicon, so that a salicide process performed in the sequential process can form a salicide region on the gate electrodes 12 which has a silicon-containing surface. An inner spacer 22 and an outer spacer 24 are selectively disposed on two sides of each gate electrode 12. The material of the inner spacer 22 and the outer spacer 24 could be high temperature oxide (HTO), silicon nitride, silicon oxide, or HCD-SiN formed by hexachlorodisilane (Si₂Cl₆), but is not limited thereto. The semiconductor structure 1 may further comprise a first liner 21 and a second liner 23 disposed inside the inner spacer 22 and the outer spacer 24, respectively, to protect the elements such as the gate electrode 12. The material of the inner spacer 22 and the outer spacer 24 includes silicon nitride, and the material of the first liner 21 and the second liner 23 includes silicon oxide. It is worth noting that, in the present invention, some unwanted spacer 25 may remain on the top and parts of two sides of the gate electrode 12, wherein the unwanted spacer 25 includes parts of the first liner 21, the first spacer 22, the second liner 23 or the second spacer 24. Those unwanted spacers 25 need to be removed before the salicide process is performed, for allowing the salicide region to be formed on the silicon-containing surface of the gate electrode 12, and modify the profile of the gate electrode 12.

Afterwards, as shown in FIG. 2, an ion implantation process 15 is entirely performed on the semiconductor structure 1, including on the substrate 10 and on the exposed top of the gate electrodes 12 to thereby form a plurality of source/drain region (S/D region) 14 on the two sides of the gate electrodes 12. In this embodiment, the ion implantation process uses an ion which has a lattice larger than a silicon atom, such as arsenic, but the invention is not limited thereto. After the ion implantation process is performed, the top of the gate electrodes 12 will be expanded due to the arsenic atoms replacing parts of the silicon atoms disposed on the top of the gate electrodes 12. The profile of each gate electrode 12 becomes “mushroom-shaped”, which means the top width of the gate electrode 12 (labeled “a” in the figure) is larger than the bottom width of the gate electrode 12 (labeled “b” in the figure). In other words, on the top of each gate electrode 12, an extrusion phenomenon occurs, forming an extrusion portion 16 on the top of each gate electrode 12. A recess 18 is disposed between each gate electrodes 12, wherein the recess 18 has a recess extension 19 disposed under the extrusion portion 16.

Afterwards, a SAB (salicide block) process is then selectively performed, to form at least one salicide block (not shown) on the substrate 10, wherein the salicide block covers the substrate 10, so that the covered place will not form a salicide region in the following salicide process. In addition, a salicide block liner (not shown) may be selectively formed before the salicide block is formed, wherein the salicide block liner is disposed under the salicide block for protecting the substrate 10. It is worth noting that, in the present invention, the unwanted spacer 25 which is disposed on the extrusion portion 16 may remain, wherein the unwanted spacer 25 may include the first liner 21, the first spacer 22, the second liner 23, the second spacer 24 or further comprise a salicide liner. As the unwanted spacer 25 is a conformal structure, it could influences the profile of the gate electrode 12 and the formation of the contact etching stop layer in the following steps, so a dry-etching process needs to be performed on the gate electrode 12 to remove the unwanted spacer 25. In the present invention, as shown in FIG. 3, a dry-etching process 17 uses an etching machine named SiCoNi (Trademark of Applied Materials, Inc.), which inputs gas such as NF₃ and NH₃ into a chamber to etch the unwanted spacer 25, but the invention is not limited to the above gases. It is worth noting that the dry-etching process 17 is an anisotropic etching process, so that only the unwanted spacer 25 will be removed, and other spacers (such as the first liner 21, the second liner 23 or the inner spacer 22) which are disposed under the extrusion portion 16 will remain.

In general, the thickness of the unwanted spacer 25 is about 20˜30 angstroms, and in a conventional process, the etching thickness set in the SiCoNi is about 40˜60 angstroms, but in the present invention, the etching thickness is set to about 80˜100 angstroms. This helps entirely remove the unwanted spacer 25 disposed on the extrusion portion 16, and also cleans the top of the gate electrode 12. Therefore, the salicide region will be formed on an exposed silicon-containing surface of the gate electrode 12, as described in the following steps. In the present invention, the dry-etching process 17 is preferably an in-situ process, but is not limited thereto; it can also be an ex-situ process.

A salicide process is then performed on each gate electrode 12 to transform parts of the gate electrode 12 into a salicide region disposed on the top of the gate electrode 12. The salicide process includes: as shown in FIG. 4, forming a metal layer 30 and a cap layer such as a TiN layer (not shown) on the gate electrode 12 and on the S/D region 14; a first RTP (rapid thermal process) 40 is then performed to react the metal layer 30 with the gate electrode 12 and the S/D region 14 for forming a plurality of silicide regions 32 on the surface of the gate electrode 12 and on the S/D region 14, wherein the temperature of the first RTP 40 is between 200° C. and 300° C. The salicide region 32 will be formed on the interface between the silicon-containing surface and the metal layer 30 while the first RTP 40 is performed. Afterwards, as shown in FIG. 5, the metal layer 30 is removed and a second RTP 42 is then performed on each salicide region 32, wherein the second RTP 42 uses a higher temperature to modify the phase of the salicide region 32, to become the salicide region 32 with lower resistance. In this embodiment, the metal layer 30 is a single layer structure or a multiple layer structure, such as cobalt, titanium, nickel, platinum, palladium or a nickel-platinum alloy (Ni/Pt) layer, but the invention is not limited thereto.

Afterwards, as shown in FIG. 6, the outer spacer 24 is removed, and a deposition process such as a CVD (chemical vapor deposition) is performed to form a contact etch stop layer (CESL) 46, covering each gate electrode 12 and the S/D region 14. In addition, the present invention may further comprise a buffer liner 45 disposed between the CESL 46 and each gate electrode 12 or the S/D region 14. The reason for removing the outer spacer 24 is to allow the stress provided by the CESL 46 to be transmitted to the gate electrode more directly. Furthermore, after the outer spacer 24 is removed, the recess 18 between each gate electrode 12 becomes wider, hence the aspect ratio of the recess 18 can be reduced which decreases the possibility of overhang occurring.

In addition, the CESL 46 can be a multi-layer structure, where each layer can have different values of stress. This means that the process of forming the CESL 46 can comprise a plurality of single-stage deposition processes, and curing processes are respectively performed after each single-stage deposition process. Therefore, each layer of the CESL 46 has a tensile stress (while the semiconductor structure is a NMOS) or compressive stress (while the semiconductor structure is a PMOS), so that the CESL 46 with multilayer can have high stress to influence the gate electrode 12.

In the present invention, because the gate electrode 12 has an extrusion portion 16, the gate electrode 12 has a “mushroom-shaped” profile. The recess extension 19 is disposed under the extrusion portion 16, meaning that cavities or voids could easily be generated between each of the gate electrodes 12 after the conformal inter dielectric layer is covered on the gate electrode 12. To solve the issues mentioned above, in the present invention, the recess extension 19 is filled by at least one spacer (which may include the first liner 21, the second liner 23 or the inner spacer 22), so that the profile of each gate electrode 12 becomes a tapered surface, which decreases the possibility of an overhang occurring. Furthermore, the unwanted spacer 25 disposed on the extrusion portion 16 is entirely removed during the dry-etching process 17, so the width difference between the upper part “a” (the width of the extrusion portion 16) and the lower part “b” (the sidewall of the recess extension 19) become smaller and the profile of the gate electrode 12 becomes tapered. Therefore, after an inter-dielectric layer is formed on the tapered surface, the cavities or voids will not easily be generated between each of the gate electrodes 12.

As shown in FIG. 7, an inter-dielectric layer (ILD) 52 is deposited on the substrate 10, and a planarization process such as a chemical mechanical polishing (CMP) is then performed to expose the gate electrode 12. Afterwards, a plurality of contact plugs 54 are formed in the ILD 52, which are electrically connected to each gate electrode 12 and the S/D region 14. The manufacturing process for forming the contact plug includes: forming a plurality of contact holes (not shown) in the ILD 52, and filling a conductive layer 56 in each contact hole, wherein the ILD 52 includes SiN or SiO₂, and the conductive layer 56 can be selected from a group consisting of a single metal Al, Ti, Ta, W, Nb, Mo, Cu, TiN, TiC, TaN, Ti/W, and composite metals such as Ti/TiN, but not limited thereto. Due to no cavities being formed after the ILD 52 is formed, the conductive layer 56 used to form the contact plugs 54 will not fill the cavities while filling the contact holes.

In summary, the semiconductor structure according of the present invention provides a spacer (which may include the first liner 21, the second 23 liner or the first spacer 22) to fill the recess extension 19 disposed under the extrusion portion 16 between any two adjacent gate electrodes. In addition, the unwanted spacer 25 is entirely removed during the dry-etching process 17, so as to modify the profile of the gate electrode before performing the salicide process. Hence, the step coverage of the ILD 52 formed in the following process can totally cover the substrate and fill the recesses 18 without forming cavities or voids. Therefore, the semiconductor structure 1 can effectively prevent adjacent contact plugs from overhang, which would lead to the contact plugs being electrically connected to each other and thereby creating short circuits.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor structure, comprising:
at least two gate electrodes disposed on a substrate, each gate electrode being mushroom-shaped and respectively having a salicide region on a top of each gate electrode, wherein the width of the salicide region is larger than the width of the gate electrode;
a recess disposed between each gate electrode, wherein the recess having an recess extension is disposed under the salicide region;
a spacer filling the recess extension, wherein the profile of each gate electrode is a tapered surface; and
a contact etching stop layer (CESL) covering the gate electrodes.

2. The semiconductor structure of claim 1, wherein the spacer is a multiple layer structure.

3. The semiconductor structure of claim 1, wherein the spacer comprises a first liner and a second liner.

4. The semiconductor structure of claim 1, further comprising an inner spacer disposed in the recess extension.

5. The semiconductor structure of claim 1, further comprising at least one source/drain region disposed in the substrate.

6. The semiconductor structure of claim 1, further comprising a buffer liner disposed between the CESL and the gate electrode.

7. The semiconductor structure of claim 1, wherein the spacer does not covers the salicide region.

8. A method for forming a semiconductor structure, comprising the following steps:
providing at least two gate electrodes disposed on a substrate;
forming a spacer disposed on two sides of each gate electrode;
performing an ion implantation process on each gate electrode while making each gate electrode becomes mushroom-shaped;
performing a dry-etching process to remove parts of the spacer, and make the profile of the gate electrodes become a tapered surface;
performing a salicide process on each gate electrode to form a salicide region disposed on each gate electrode, wherein the width of the salicide region is larger than the width of the gate electrode; and
forming a contact etching stop layer (CESL) on each gate electrode.

9. The method of claim 8, wherein the ion implantation process uses an ion with a larger lattice than a silicon atom as the implanted ion.

10. The method of claim 8, wherein the ion implantation process uses arsenic (As) as the implanted ion.

11. The method of claim 8, further comprising a buffer liner disposed between the CESL and the gate electrode.

12. The method of claim 8, further comprising a recess disposed between each gate electrode, wherein the recess has a recess extension disposed under the salicide region.

13. The method of claim 12, further comprising a first liner and a second liner disposed in the recess extension.

14. The method of claim 8, wherein the spacer comprises an inner spacer and an outer spacer.

15. The method of claim 14, further comprising removing the outer spacer completely before the CESL is formed.

16. The method of claim 14, wherein the inner spacer is disposed in the recess extension.

17. The method of claim 8, further comprising at least one source/drain region disposed in the substrate.

18. The method of claim 8, wherein the dry-etching process removes parts of the spacer which is disposed on the salicide region.

19. The method of claim 18, wherein the dry-etching process is an in-situ process or an ex-situ process.
